(19) United States
(12) Patent Application Publication
(10) Pub. No.: US 2009/0218703 A1
(43) Pub. Date: Sep. 3, 2009

(54) Lamination Tape for Reducing Chip Warpage and Semiconductor Device Containing Such Tape

(76) Inventors: Soo Gil Park, Radebeul (DE); Kimyung Yoon, Dresden (DE)

Correspondence Address: SLATER & MATSIL, L.L.P., 17950 PRESTON ROAD, SUITE 1000, DALLAS, TX, 75252, US

(21) Appl. No.: 12/039,739

(22) Filed: Feb. 29, 2008

(51) Int. Cl. H01L 23/373; B32B 15/04

(52) U.S. Cl. 257/783; 428/343; 257/E23.002; 257/E23.11

(57) ABSTRACT

A lamination tape is disclosed which includes a base film with an adhesive layer on one side wherein the coefficient of thermal expansion (CTE) of the adhesive layer is adapted so as to reduce warpage of a semiconductor die when the lamination tape is attached to the passive side of the semiconductor die.

### TECHNICAL FIELD

Various embodiments are related to a lamination tape and a semiconductor device containing such tape.

### BACKGROUND

In the manufacture of semiconductor devices, a plurality of chips is structured on a semiconductor wafer, which is subsequently cut or sawn in order to singulate the chips into dice. The dice are further processed to become parts of a so-called package or device. Opposite surfaces of the wafer or die, respectively, have different properties in terms of thermal expansion. This is mainly due to the active structures being disposed on one side only. Arrangement of additional structures, such as for instance redistribution layers, on the active side of the wafer or the die add to the disparate properties of the opposing surfaces.

The difference in the coefficients of thermal expansion of the opposing sides of the wafer results in the warpage of the wafer or die, respectively, which makes handling of the wafer or die and attaching the die to a substrate or the like extremely difficult. In recent years, the thickness of the wafers has constantly been reduced in order to cut down on the usage of semiconductor material and to provide for small dimensions of multichip packages. This in turn amplified the effect of the different thermal properties of the opposing sides of the wafer, namely the induction of warpage due to temperature changes.

### SUMMARY OF THE INVENTION

In a first embodiment, a lamination tape includes a dielectric base film with at least one adhesive layer on one side and a reinforcement component adjacent the dielectric base film. The lamination tape has a coefficient of thermal expansion (CTE) that is adapted so as to reduce warpage of a semiconductor die when the lamination tape is attached to a passive side of the semiconductor die.

In another embodiment, a semiconductor device includes a semiconductor die having an active side with structures disposed thereat and a passive side opposite the active side. A lamination tape is attached to the passive side of the semiconductor die. The lamination tape having a coefficient of thermal expansion (CTE) that is adapted to reduce warpage of the semiconductor die.

### BRIEF DESCRIPTION OF THE DRAWINGS

For a better understanding of the present disclosure, figures are provided in which:

FIGS. 1a and 1b, collectively FIG. 1, show the effect of unbalanced versus balanced CTE between the active and passive sides of a die, and

FIGS. 2a-2c, collectively FIG. 2, show an exemplary embodiment of a lamination tape disclosed herein.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

In various embodiments, a lamination tape is disclosed. This tape comprises a base film with an adhesive layer on one side wherein the coefficient of thermal expansion (CTE) of the adhesive layer is adapted so as to reduce warpage of a semiconductor die when the lamination tape is attached to the passive side of the semiconductor die.

In one embodiment, the material of the adhesive layer is selected so as to have a CTE which is approximately equal to the CTE of structures disposed on the active side of the semiconductor die. For example, in one embodiment, where the semiconductor die comprises copper structures on its active side, the material of the adhesive layer is selected so as to have a CTE which is similar to the CTE of copper. The coefficient of thermal expansion of copper (symbol Cu) is approximately 17·10⁻⁶ K⁻¹. The coefficient of thermal expansion of the adhesive layer may, therefore, be selected from within the range of about 10·10⁻⁶ K⁻¹ to about 25·10⁻⁶ K⁻¹. For instance, the coefficient of thermal expansion of the adhesive layer may be selected from within the range of about 14·10⁻⁶ K⁻¹ to about 20·10⁻⁶ K⁻¹ to get even closer to the CTE of copper. In an analogous manner, the CTE of the adhesive layer may be selected so as to be similar to any other material of which structures disposed on the active side of the semiconductor die may be manufactured.

In another embodiment, the CTE of the adhesive layer is controlled by an additive embedded in the material of the adhesive layer. The additive may, for instance, be a granular or powdery material mixed into the adhesive material. The additive may, however, also be a sheet-like material embedded in the adhesive layer or sandwiched between two adhesive layers. The sheet-like material may comprise a plurality of holes, slits or the like, which may give it the appearance of a lattice, grid, mesh, grating or the like. The material of the additive may be a metal, such as for instance copper, silver or gold. Especially in, but not restricted to, cases where the structures on the active side of the semiconductor die, which govern thermal expansion of the active side, are made from a non-metallic material, the material of the additive may also be a non-metal.

A semiconductor device comprising at least one semiconductor die is proposed wherein a lamination tape is attached to the passive side of the semiconductor die. The lamination tape may be attached to the backside of the wafer before the dice are singulated. Thus, only one attachment step is required and each of the singulated dice will carry a portion of the lamination tape on its backside. However, it is also possible to first singulate the dice and then attach a piece of lamination tape to every single die.

Various embodiments will now be described with respect to the figures.

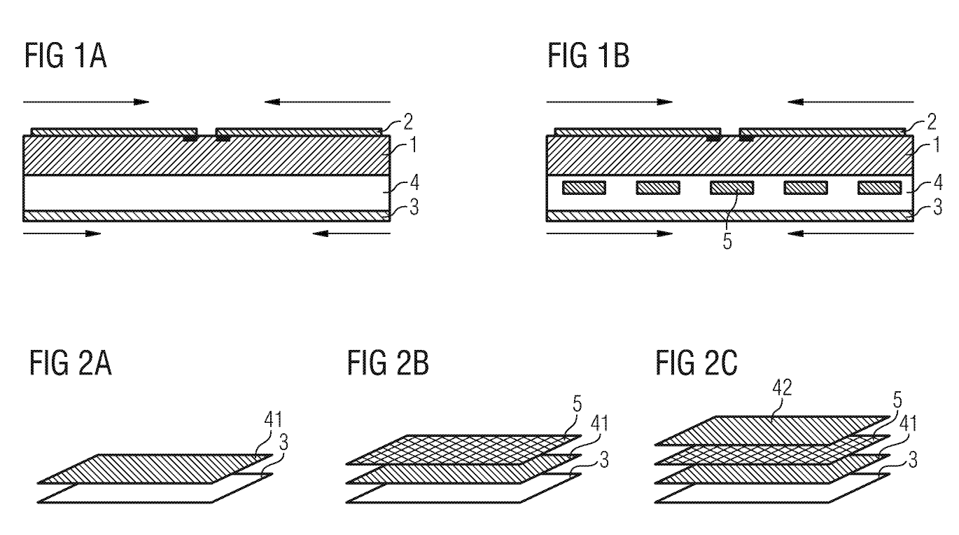

Referring first to FIG. 1, a semiconductor die 1 has a redistribution layer 2 and other active structures disposed on its active side (the top side in the drawing). On the bottom side, a lamination tape is adhered to the die. The lamination tape comprises a base film 3 with an adhesive layer 4 on one side. The coefficient of thermal expansion (CTE) of the lamination tape of the device of FIG. 1a is not adapted to the CTE of the die and therefore, the expansion or shrinkage of the top side (represented by the upper arrows) is different from the expansion or shrinkage of the bottom side (represented by the lower arrows), leading to warpage of the semiconductor device.

In contrast, in FIG. 1b, the CTE of the lamination tape is adapted to the CTE of the die 1 and its active structures 2. A metal lattice sheet 5 is embedded in the adhesive layer 4 on the base film 3 of the lamination tape. Thus, the CTE of the lamination tape is adapted to the CTE of the die, leading to substantially equal values of thermal expansion or shrinkage of the upper side (represented by the upper arrows) and of the bottom side (represented by the lower arrows), respectively. The balanced CTE of the top and bottom side of the semiconductor device helps to avoid or at least to decrease temperature-induced warpage.

FIG. 2 shows an exemplary embodiment of a manufacturing method for such lamination tape comprising several different layers. For better visibility, the layers, though in reality stacked one on top of the other, are drawn separately. Referring first to FIG. 2a, a first adhesive layer 41 is printed on a base film 3. Next, a CTE-balanced grating sheet 5 is put on top of the first adhesive layer 41, as shown in FIG. 2b. Finally, the additive component 5 is covered by a second adhesive layer 42. This step is shown in FIG. 2c. Through the openings in the grating sheet 5, the first and second adhesive layers 41, 42 merge to constitute an adhesive layer in which an additive component 5 is embedded.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A lamination tape comprising:
a dielectric base film with at least one adhesive layer on one side; and
a reinforcement component adjacent the dielectric base film;
wherein the lamination tape has a coefficient of thermal expansion (CTE) that is adapted so as to reduce warpage of a semiconductor die when the lamination tape is attached to a passive side of the semiconductor die.

2. The lamination tape of claim 1, wherein the CTE of the reinforcement component is approximately equal to the CTE of structures disposed on an active side of the semiconductor die, the active side opposite the passive side.

3. The lamination tape of claim 1, wherein the reinforcement component comprises a granular or powdery material.

4. The lamination tape of claim 1, wherein the reinforcement component comprises a reinforcement layer attached to or embedded in the base film of the lamination tape.

5. The lamination tape of claim 4, wherein the reinforcement layer comprises a plurality of openings.

6. The lamination tape of claim 5, wherein the reinforcement layer comprises a sheet-like additive component that has the structure of a lattice, grid, mesh or grating.

7. The lamination tape of claim 1, wherein the reinforcement component comprises a granular or powdery material, the material comprising a metal.

8. A semiconductor device comprising:
a semiconductor die having an active side with structures disposed thereat and a passive side opposite the active side; and
a lamination tape attached to the passive side of the semiconductor die, the lamination tape having a coefficient of thermal expansion (CTE) that is adapted to reduce warpage of the semiconductor die.

9. The semiconductor device of claim 1, wherein the CTE of the lamination tape is approximately equal to the CTE of the structures disposed at the active side of the semiconductor die.

10. The semiconductor device of claim 1, wherein the lamination tape comprises a reinforcing component.

11. The semiconductor device of claim 10, wherein the reinforcing component has a CTE that is approximately equal to a CTE of the structures disposed at the active side of the semiconductor die.

12. The semiconductor device of claim 10, wherein the reinforcing component comprises a granular or powdery material.

13. The semiconductor device of claim 10, wherein the reinforcing component comprises a sheet-like material.

14. The semiconductor device of claim 13, wherein the sheet-like reinforcing component comprises a plurality of holes or slits.

15. The semiconductor device of claim 14, wherein the sheet-like reinforcing component has the structure of a lattice, grid, mesh or grating.

16. The semiconductor device of claim 14, wherein the reinforcing component comprises a metal.

17. A semiconductor device comprising:
at least one semiconductor die; and
a lamination tape, wherein the lamination tape comprises a base film with at least one adhesive layer on one side that is attached to a passive side of the semiconductor die.

18. A semiconductor device comprising:
a semiconductor die;
metal interconnect structures formed at an active surface of the semiconductor die;
an adhesive layer disposed on a passive side of the semiconductor die, wherein the adhesive layer comprises a metal that is the same material as the metal interconnect structures.

19. The semiconductor device of claim 18, wherein the metal interconnect structures comprise copper and wherein the lamination tape comprises copper.

20. The semiconductor device of claim 18, wherein the lamination tape further comprises a base material, the metal being embedded in the base material.

21. A semiconductor device comprising:
a semiconductor die;
copper structures formed at an active surface of the semiconductor die;
an adhesive layer disposed on a passive side of the semiconductor die, wherein the adhesive layer has a coefficient of thermal expansion (CTE) in the range of about 10·10⁻⁶ K⁻¹ to about 25·10⁻⁶ K⁻¹.

22. The semiconductor device of claim 21, wherein the adhesive layer has a coefficient of thermal expansion (CTE) in the range of about 14·10⁻⁶ K⁻¹ to about 20·10⁻⁶ K⁻¹.
